(19) United States
(12) Patent Application Publication
(10) Pub. No.: US 2023/0111103 A1
(43) Pub. Date: Apr. 13, 2023

(54) LED DISPLAY MODULE AND DISPLAY DEVICE

(71) Applicant: FOSHAN NATIONSTAR OPTOELECTRONICS CO., LTD., Foshan (CN)

(72) Inventors: Kuai Qin, Foshan (CN); Heng Guo, Foshan (CN); Bin Cai, Foshan (CN); Feng Gu, Foshan (CN); Fangping He, Foshan (CN)

(73) Assignee: FOSHAN NATIONSTAR OPTOELECTRONICS CO., LTD., Foshan (CN)

(21) Appl. No.: 17/936,645

(22) Filed: Sep. 29, 2022

(30) Foreign Application Priority Data
Oct. 13, 2021 (CN) 202111192853.6
Oct. 13, 2021 (CN) 202122469653.2

(51) Int. Cl. H01L 25/075; H01L 33/62; H01L 27/15; H01L 33/38

(52) U.S. Cl. CPC H01L 25/0753; H01L 27/156; H01L 33/62; H01L 33/382

(57) ABSTRACT

Provided are an LED display module and a display device. The LED display module includes LED display units and a circuit board. Each LED display unit includes pixel units. Each pixel unit includes LED light-emitting chips. A surface of the circuit board is provided with a circuit layer. The circuit layer includes first wirings and second wirings that do not cross each other. A-electrodes of LED light-emitting chips in an i-th row of pixel units in a current LED display unit and in an i-th row of pixel units in a subsequent LED display unit are electrically connected by one first wiring. B-electrodes of LED light-emitting chips of a same color in a j-th column of pixel units in a current LED display unit and in a j-th column of pixel units in a subsequent LED display unit are electrically connected by one second wiring.

### CROSS-REFERENCE TO RELATED APPLICATIONS

This application claims priorities to Chinese Patent Application No. 202111192853.6 filed with the Chinese Intellectual Property Administration (CNIPA) on Oct. 13, 2021, and Chinese Patent Application No. 202122469653.2 filed with the CNIPA on Oct. 13, 2021, the disclosures of which are incorporated herein by reference in their entireties.

### TECHNICAL FIELD

Embodiments of the present disclosure relate to light-emitting diode (LED) display technology, in particular, to an LED display module and a display device.

### BACKGROUND

Due to advantages of high gray scale, large visual angle, low power consumption, and customizable screen shape, LED display screens are widely used in various fields such as industry, traffic, commercial advertisement and information distribution.

The LED display screen is composed of an LED display unit composed of a single pixel unit, and a multiple-in-one LED display unit composed of multiple pixel units is also provided on the market. In the LED display unit, the cathodes of all the LED light-emitting chips in the same row of pixel units are each connected to one cathode pin corresponding to the row of pixel units, and the anodes of the LED light-emitting chips of the same light-emission color in the same column of pixel units are connected to one corresponding anode pin. When the display module is formed, it is necessary to solder pins of multiple LED display units to the circuit board. Cathode pins of two adjacent LED display units in each row are electrically connected through connection lines in the circuit board, and anode pins corresponding to light-emitting chips of the same light-emission color of two adjacent LED display units in each column are electrically connected through connection lines in the circuit board.

In the circuit board, first wirings connecting the cathode pins extend in a row direction, and second wirings connecting the anode pins extend in a column direction. If the first wirings and the second wirings are located in the same layer, there are crossing portions there between so that the lines may be shorted. In order to avoid the short-circuit problem caused by wiring crossing, it is necessary to design the first wirings and the second wirings at different layers of the circuit board, and the design of wirings in multilayers increases the manufacturing cost of the circuit board.

### SUMMARY

An LED display module and a display device are provided according to embodiments of the present disclosure, which can simplify the design of a circuit board and reduce the manufacturing cost of the circuit board.

In a first aspect, an LED display module is provided according to an embodiment of the present disclosure, and the LED display module includes multiple LED display units arranged in an array, and a circuit board. Each of the multiple LED display units includes m rows and n columns of pixel units, each of the pixel units includes multiple LED light-emitting chips of different light-emission colors, each of the LED light-emitting chips has an A-electrode and a B-electrode, where a polarity of the A-electrode is opposite to a polarity of the B-electrode, and m and n are positive integers greater than or equal to 1. The multiple LED display units are arranged on the circuit board, a surface of the circuit board close to the multiple LED display units is provided with a circuit layer, the circuit layer includes multiple first wirings and multiple second wirings, the first wirings extend in a row direction, the second wirings extend in a column direction, and the first wirings and the second wirings do not cross each other.

In each row of LED display units among the multiple LED display units, A-electrodes of LED light-emitting chips in an i-th row of pixel units in a current LED display unit and A-electrodes of LED light-emitting chips in an i-th row of pixel units in a subsequent LED display unit are electrically connected by one first wiring; in each column of LED display units among the multiple LED display units, B-electrodes of LED light-emitting chips of a same color in a j-th column of pixel units in a current LED display unit and in a j-th column of pixel units in a subsequent LED display unit are electrically connected by one second wiring; and 1 ≤ i ≤ m, 1 ≤ j ≤ n, and i and j are positive integers.

In an embodiment, one LED display unit further includes a substrate, the substrate is provided with a pin layer electrically connected to the pixel units, the pixel units and the pin layer are respectively provided on two sides of the substrate, and the pin layer includes multiple A-electrode pins; each row of pixel units in the LED display unit is provided with at least two A-electrode pins, the at least two A-electrode pins include a first A-electrode pin and a second A-electrode pin, the first A-electrode pin and the second A-electrode pin are arranged in the row direction, and the first A-electrode pin is electrically connected to the second A-electrode pin; A-electrodes of LED light-emitting chips in each row of pixel units of the LED display unit are electrically connected to a respective one first A-electrode pin and a respective one second A-electrode pin corresponding to the row of pixel units; and in each row of LED display units, a second A-electrode pin corresponding to an i-th row of pixel units in a current LED display unit and a first A-electrode pin corresponding to an i-th row of pixel units in a subsequent LED display unit are electrically connected by one first wiring.

In an embodiment, the pin layer further includes multiple B-electrode pins, and the multiple B-electrode pins include first B-electrode pins; each column of pixel units in the LED display unit is provided with the first B-electrode pins, and a number of the first B-electrode pins is the same as a number of LED light-emitting chips in each column of pixel units; B-electrodes of LED light-emitting chips of a same light-emission color in each column of pixel units in the LED display unit are electrically connected to a respective one of the first B-electrode pins in the column of pixel units; and in each column of LED display units, first B-electrode pins corresponding to LED light-emitting chips of a same light-emission color in a j-th column of pixel units in a current LED display unit and in a j-th column of pixel units in a subsequent LED display unit are electrically connected by one second wiring.

In an embodiment, each row of pixel units in the LED display unit is provided with two A-electrode pins, and the two A-electrode pins are the first A-electrode pin and the second A-electrode pin, respectively; A-electrodes of LED light-emitting chips in each row of pixel units in the LED display unit are electrically connected to the first A-electrode pin and the second A-electrode pin corresponding to the row of pixel units; and in each row of the LED display units, a second A-electrode pin corresponding to an i-th row of pixel units in a current LED display unit and a first A-electrode pin corresponding to an i-th row of pixel units in a subsequent LED display unit are electrically connected by one first wiring.

In an embodiment, the first A-electrode pin and the second A-electrode pin corresponding to each row of pixel units are arranged at a first edge on the substrate and a second edge on the substrate in the row direction, respectively, where the first edge is opposite to the second edge.

In an embodiment, the first B-electrode pins are arranged on the substrate in a staggered manner, and the first B-electrode pins are arranged in a region surrounded by first A-electrode pins and second A-electrode pins.

In an embodiment, the B-electrode pins further includes a second B-electrode pin, at least one of the first B-electrode pins is provided with one second B-electrode pin, and the at least one of the first B-electrode pins is electrically connected to the second B-electrode pin; in at least one column of pixel units in the LED display unit, a B-electrode of at least one LED light-emitting chip of LED light-emitting chips of a same light-emission color is electrically connected to one first B-electrode pin and one second B-electrode pin corresponding to the at least one column of pixel units; and in each column of LED display units, a second B-electrode pin corresponding to a j-th column of pixel units in a current LED display unit is electrically connected to a first B-electrode pin corresponding to the j-th column of pixel units in a subsequent LED display unit by the second wiring.

In an embodiment, one first B-electrode pin and one second B-electrode pin corresponding to the one first B-electrode pin are arranged at a third edge on the substrate and a fourth edge on the substrate in the column direction, respectively, where the third edge is opposite to the fourth edge.

In an embodiment, the LED display unit further includes an insulating layer, and the insulating layer covers connection lines connecting the multiple A-electrode pins and connecting the multiple B-electrode pins in the pin layer and exposes the multiple A-electrode pins and the multiple B-electrode pins

In an embodiment, the insulating layer is provided with a window passing through the insulating layer, and the window exposes a part of the connection lines in the pin layer.

In an embodiment, the multiple first wirings are arranged between two adjacent LED display units, and the multiple second wirings pass through vertical projections of the multiple LED display units on the circuit board.

In an embodiment, the first B-electrode pins are arranged on the substrate in a staggered manner.

In an embodiment, the first B-electrode pins are located at a third edge on the substrate and a fourth edge on the substrate, respectively, where the third edge is opposite to the fourth edge.

In an embodiment, the LED display unit includes three LED light-emitting chips of different light-emission colors, and the pin layer includes three first B-electrode pins, where one first B-electrode pin of the three first B-electrode pins is located between the first A-electrode pin and the second A-electrode pin.

In an embodiment, an area of the one first B-electrode pins between the first A-electrode pin and the second A-electrode pin is different from an area of each of the other two first B-electrode pins of the three first B-electrode pins.

In an embodiment, the LED display unit further includes a pad layer, the pad layer is electrically connected to the pin layer, and LED light-emitting chips of the LED display unit are fixed onto the pad layer and electrically connected to the pad layer; the pad layer includes first pads and second pads, a number of the first pads is the same as a number of the LED light-emitting chips, and a number of the second pads is the same as the number of the LED light-emitting chips, each of B-electrodes of the LED light-emitting chips is electrically connected to a respective one of the first pads, and each of A-electrodes of the LED light-emitting chips is electrically connected to a respective one of the second pads; each of the first pads is electrically connected to a respective one of the first B-electrode pins; and the second pads are electrically connected together and are electrically connected to the first A-electrode pin and the second A-electrode pin.

In an embodiment, the second pads are electrically connected to the first A-electrode pin and the second A-electrode pin through a metal via; or the second pads are electrically connected to the first A-electrode pin and the second A-electrode pin through a metal via and a connection line, and the connection line is located on the pin layer and is electrically connected to the first A-electrode pin and the second A-electrode pin.

In an embodiment, the second pads are electrically connected by a connection line in the pad layer, or the second pads are an integrated structure, to form a common pad.

In a second aspect, a display device is provided according to an embodiment of the present disclosure, and the display device includes the LED display module according to the first aspect of the present disclosure.

### BRIEF DESCRIPTION OF DRAWINGS

The present disclosure is further described in detail according to the drawings and embodiments.

FIG. 1 is a top view of an LED display unit in the related art;

FIG. 2 is a bottom view of the LED display unit in FIG. 1;

FIG. 3 is a wiring diagram showing connection of common cathode pins of LED light-emitting chips of a circuit board;

FIG. 4 is a wiring diagram showing connection of anode pins of red LED light-emitting chips of a circuit board;

FIG. 5 is a wiring diagram showing connection of anode pins of green LED light-emitting chips of a circuit board;

FIG. 6 is a wiring diagram showing connection of anode pins of blue LED light-emitting chips of a circuit board;

FIG. 7 is a wiring diagram of a circuit board in a display module in the related art;

FIG. 8 is a top view of another LED display unit in the related art;

FIG. 9 is a bottom view of the LED display unit in FIG. 8;

FIG. 10 is a wiring diagram showing another connection of cathode pins of LED light-emitting chips of a circuit board;

FIG. 11 is a wiring diagram showing connection of anode pins of red LED light-emitting chips of a circuit board;

FIG. 12 is a wiring diagram showing connection of anode pins of green LED light-emitting chips and connection of anode pins of blue LED light-emitting chips of a circuit board;

FIG. 13 is a wiring diagram of a circuit board in another display module in the related art;

FIG. 14 is a partial structural diagram of an LED display module according to an embodiment of the present disclosure;

FIG. 15 is a top view of an LED display unit according to an embodiment of the present disclosure;

FIG. 16 is a bottom view of the LED display unit in FIG. 15;

FIG. 17 is a bottom view of another LED display unit according to an embodiment of the present disclosure;

FIG. 18 is a top view of another LED display unit according to an embodiment of the present disclosure;

FIG. 19 is a bottom view of the LED display unit in FIG. 18;

FIG. 20 is a top view of another LED display unit according to an embodiment of the present disclosure;

FIG. 21 is a bottom view of the LED display unit in FIG. 20;

FIG. 22 is a partial structural diagram of another LED display module according to an embodiment of the present disclosure;

FIG. 23 is a top view of another LED display unit according to an embodiment of the present disclosure;

FIG. 24 is a bottom view of the LED display unit in FIG. 23;

FIG. 25 is a partial structural diagram of another LED display module according to an embodiment of the present disclosure;

FIG. 26 is a top view of another LED display unit according to an embodiment of the present disclosure;

FIG. 27 is a bottom view of the LED display unit in FIG. 26;

FIG. 28 is a top view of another LED display unit according to an embodiment of the present disclosure;

FIG. 29 is a bottom view of the LED display unit in FIG. 28;

FIG. 30 is a partial structural diagram of another LED display module according to an embodiment of the present disclosure;

FIG. 31 is a top view of another LED display unit according to an embodiment of the present disclosure; and

FIG. 32 is a bottom view of the LED display unit in FIG. 31.

### DETAILED DESCRIPTION

In order for the technical issues to be addressed, the technical schemes employed, and the technical effects achieved by the present disclosure to be clearer, the technical schemes of embodiments of the present disclosure are further described in detail with reference to the drawings. Apparently, the embodiments described are only a part of the embodiments of the present disclosure, rather than all of the embodiments. Based on embodiments of the present disclosure, all other embodiments obtained by the person skilled in the art are within the scope of the present disclosure on the premise that no creative efforts are made.

In the description of the present disclosure, unless otherwise expressly specified and limited, the terms “connected to each other”, “connected”, or “fixed” are to be construed in a broad sense, for example, as permanently connected, detachably connected, or integrated; mechanically connected or electrically connected; directly connected to each other or indirectly connected to each other via an intermediary; or internally connection of two components or interaction between two components. For those of ordinary skill in the art, specific meanings of the preceding terms in the present invention may be construed based on specific situations.

In the present disclosure, unless otherwise expressly specified and limited, when a first feature is described as “above” or “below” a second feature, the first feature and the second feature may be in direct contact, or be in contact via another feature between the two features. Moreover, when the first feature is described as “on”, “above” or “over” the second feature, the first feature is right on, above or over the second feature or the first feature is obliquely on, above or over the second feature, or the first feature is simply at a higher level than the second feature. When the first feature is described as “under”, “below” or “underneath” the second feature, the first feature is right under, below or underneath the second feature or the first feature is obliquely under, below or underneath the second feature, or the first feature is simply at a lower level than the second feature. In addition, the terms “first” and “second” are used only to distinguish between descriptions and have no special meaning.

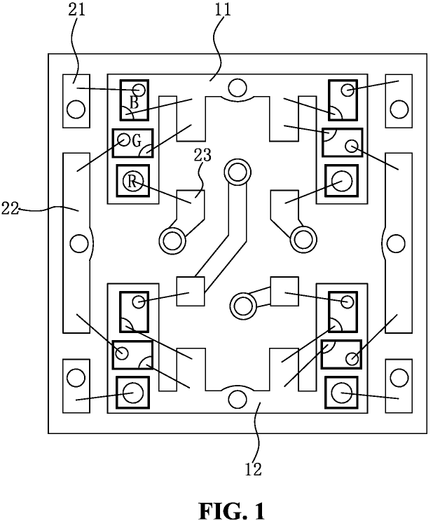

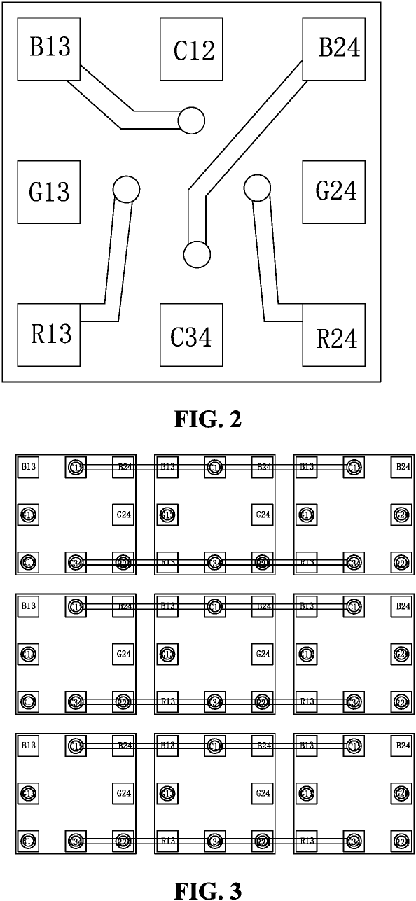

FIG. 1 is a top view of an LED display unit in the related art, and FIG. 2 is a bottom view of the LED display unit in FIG. 1. As shown in FIG. 1 and FIG. 2, the LED display unit is a four-in-one display unit which includes four pixel units, and each of the pixel units includes three LED light-emitting chips of red, green, and blue (R, G, and B).

Illustratively, in a first row of pixel units, cathodes of all LED light-emitting chips of two pixel units are each connected to a common pad 11, and the common pad 11 is connected to a common cathode pin C12 through a metal via. In a second row of pixel units, the cathodes of all LED light-emitting chips of two pixel units are each connected to a common pad 12, and the common pad 12 is connected to a common cathode pin C34 through a metal via. In a first column of pixel units, an anode of a blue LED light-emitting chip B is connected to a corresponding anode pad 21, and is electrically connected to an anode pin B13 corresponding to the blue LED light-emitting chip B through a connection line and a metal via. In the first column of pixel units, an anode of a green LED light-emitting chip G is connected to a corresponding anode pad 22, and is electrically connected to an anode pin G13 corresponding to the green LED light-emitting chip G through a connection line and a metal via. Similarly, in the first column of pixel units, an anode of a red LED light-emitting chip R is connected to a corresponding anode pad 23, and is electrically connected to an anode pin R13 corresponding to the red LED light-emitting chip R through a connection line and a metal via. In a second column of pixel units, anode pins corresponding to a blue LED light-emitting chip, a green LED light-emitting chip, and a red LED light-emitting chip are anode pins B24, G24, and R24, respectively, and the connection relationships are similar to those of the first column of pixel units, and details are not described herein in the embodiment of the present disclosure.

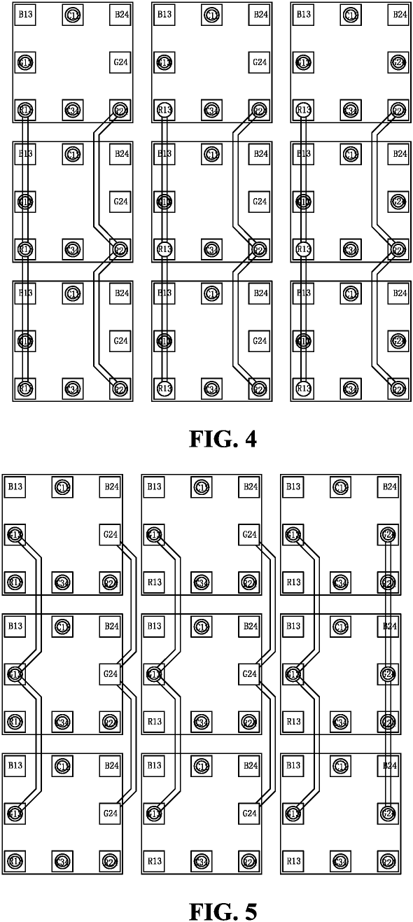

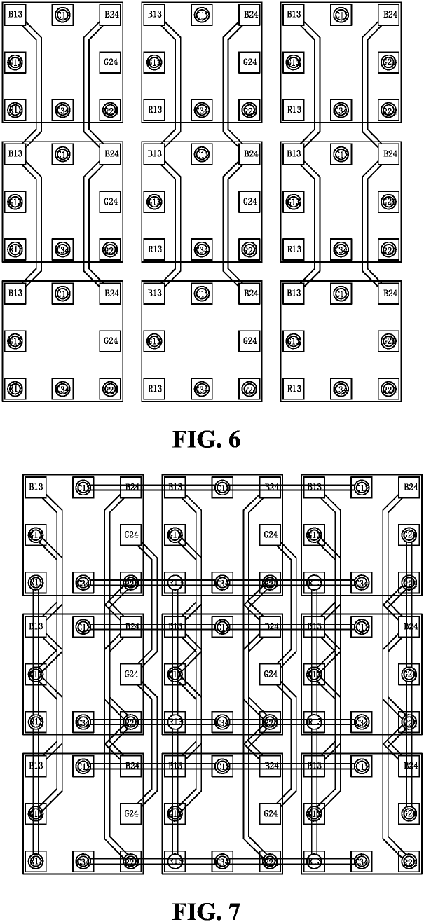

As described above, when the display module is formed, it is necessary to solder pins of multiple LED display units to the circuit board. Common cathode pins of two adjacent LED display units in each row are electrically connected by wirings in the circuit board, and anode pins corresponding to light-emitting chips of a same light-emission color in two adjacent LED display units in each column are electrically connected by wirings in the circuit board. FIG. 3 is a wiring diagram showing connection of common cathode pins of LED light-emitting chips of a circuit board, FIG. 4 is a wiring diagram showing connection of anode pins of red LED light-emitting chips of a circuit board, FIG. 5 is a wiring diagram showing connection of anode pins of green LED light-emitting chips of a circuit board, FIG. 6 a wiring diagram showing connection of anode pins of blue LED light-emitting chips of a circuit board, and FIG. 7 is a wiring diagram of a circuit board in a display module in the related art. As shown in FIG. 3 to FIG. 7, there are crossing portions between the wirings for connecting common cathode pins and other wirings for connecting anode pins, and therefore, in order to avoid a short-circuit issue caused by wiring crossing, a circuit board is required to be configured to have multiple wiring layers, which undoubtedly increases the difficulty in preparing the circuit board and increases the production cost.

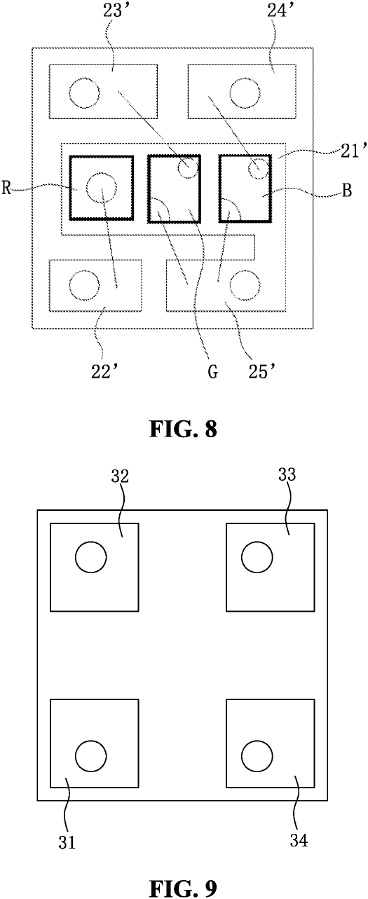

FIG. 8 is a top view of an LED display unit in the related art, and FIG. 9 is a bottom view of the LED display unit in FIG. 8. As shown in FIG. 8 and FIG. 9, the LED display unit includes three LED light-emitting chips R, G, and B, and the three LED light-emitting chips R, G, and B (for example, light-emitting chips of three colors red, green and blue) are fixed to a solid crystal pad 21′. B-electrodes (e.g., anodes) of the three LED light-emitting chips R, G and B are electrically connected to corresponding first pad 22′, first pad 23′, first pad 24′ by metal lines, respectively. An A-electrode (e.g., a cathode) of the LED light-emitting chip R is fixed to the solid crystal pad 21′ by a conductive material (e.g., tin), so as to be electrically connected to the solid crystal pad 21′. A-electrodes of the LED light-emitting chips G and B are electrically connected to the second pad 25′ by metal lines, respectively. The second pad 25′ and the solid crystal pad 21′ are formed into an integral structure, so that the A-electrodes of the three LED light-emitting chips R, G and B are electrically connected to the second pad 25′.

The first pads 22′, 23′ and 24′ are correspondingly electrically connected to B-electrode pins 31, 32, 33 on a back side through metal vias respectively, and the second pad 25′ is electrically connected to an A-electrode pin 34 on a back side through a metal via.

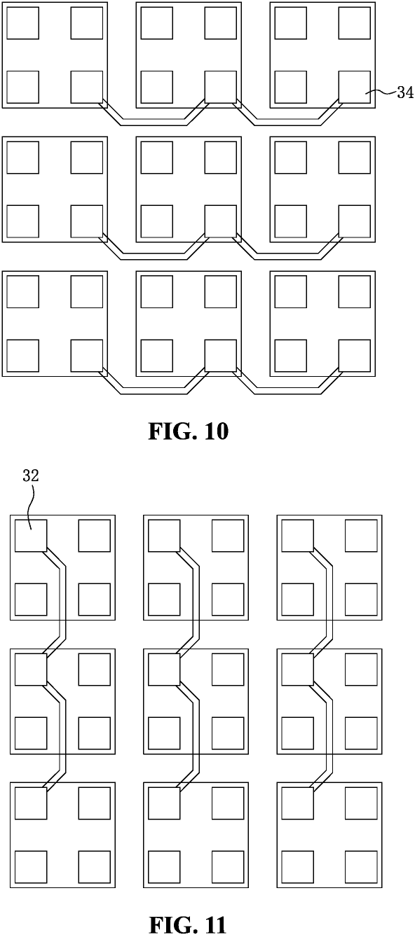

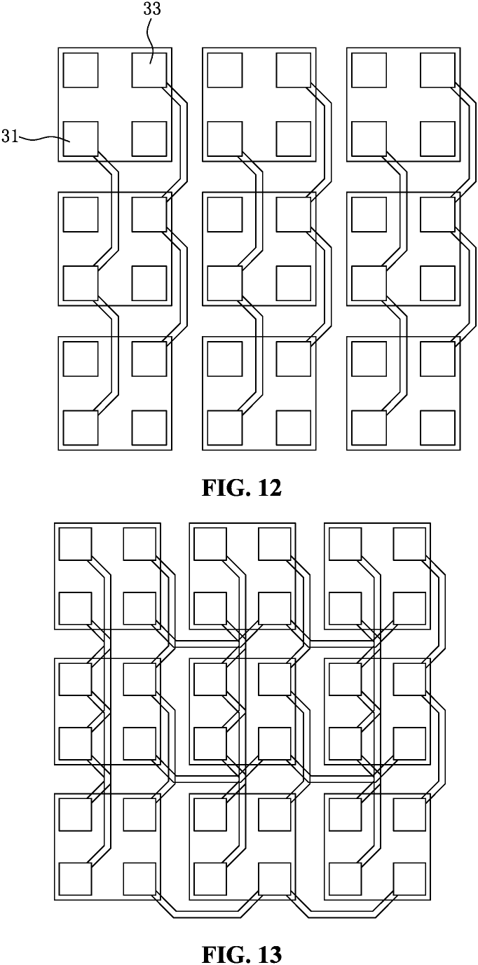

As described above, in forming the display module, it is necessary to solder pins of an LED display unit composed of an individual pixel unit to a circuit board. Cathode pins of two adjacent pixel units in each row are electrically connected by wirings in the circuit board, and anode pins corresponding to light-emitting chips of a same light-emission color in two adjacent pixel units in each column are electrically connected by wirings in the circuit board. FIG. 10 is a wiring diagram showing connection of cathode pins of light-emitting chips of a circuit board, FIG. 11 is a wiring diagram showing connection of anode pins of red LED light-emitting chips of a circuit board, FIG. 12 is a wiring diagram showing connection of anode pins of green LED light-emitting chips and connection of anode pins of blue LED light-emitting chips of a circuit board, and FIG. 13 is a wiring diagram of a circuit board in a display module in the related art. As shown in FIG. 10 to FIG. 13, there are crossing portions between the wirings for connecting cathode pins and other wirings for connecting anode pins, and therefore, in order to avoid a short-circuit issue caused by wiring crossing, a circuit layer is required to be provided separately for the wirings in FIG. 10. In addition, since there are crossing portions between the wirings in FIG. 11 and the wirings in FIG. 12 as well, it is necessary to provide circuit layers separately, and the circuit board is required to be configured as a circuit board with three circuit layers in total. This undoubtedly increases the difficulty in manufacturing the circuit board and increases the production cost.

In view of the above issues, an LED display module is provided according to an embodiment of the present disclosure, to address the issue that when LED display units are soldered to a circuit board, the circuit board is required to be configured with multiple circuit layers due to wiring crossing, resulting in high manufacturing cost of the circuit board. The LED display module according to the embodiment of the present disclosure includes multiple LED display units arranged in an array and a circuit board.

The LED display unit includes m rows and n columns of pixel units, the pixel unit includes several LED light-emitting chips of different light-emission colors, and the LED light-emitting chip has an A-electrode and a B-electrode of opposite polarities, where m and n are positive integers greater than or equal to 1.

The LED display units are arranged on the circuit board, a surface of the circuit board close to the LED display units is provided with a circuit layer, the circuit layer includes several first wirings and several second wirings, the first wirings extend in a row direction, the second wirings extend in a column direction, and the first wirings and the second wirings do not cross each other.

In each row of LED display units, A-electrodes of LED light-emitting chips in an i-th row of pixel units in a current LED display unit and in an i-th row of pixel units in a subsequent LED display unit are electrically connected by the first wiring.

In each column of LED display units, B-electrodes of LED light-emitting chips of a same color in a j-th column of pixel units in a current LED display unit and in a j-th column of pixel units in a subsequent LED display unit are electrically connected by the second wiring, where, 1 ≤ i ≤ m, 1 ≤ j ≤ n, and i and j are positive integers.

The A-electrodes of all the LED light-emitting chips in the same row of pixels in each row of LED display units are connected by the first wirings on the circuit layer, and the B-electrodes of the LED light-emitting chips of a same color in the same column of pixel units in each column of LED display units are connected by the second wirings on the circuit layer, the first wirings and the second wirings extend in the row direction and the column direction respectively, and the first wirings and the second wirings do not cross each other, so that all the wirings connecting the electrodes of the LED light-emitting chips on the circuit board can be arranged on the same circuit layer of the circuit board, thereby reducing the difficulty and cost of manufacturing the circuit board.

In order that the technical schemes of the present disclosure can be more clearly understood by the person skilled in the art, the schemes of the present disclosure are exemplified in conjunction with specific examples.

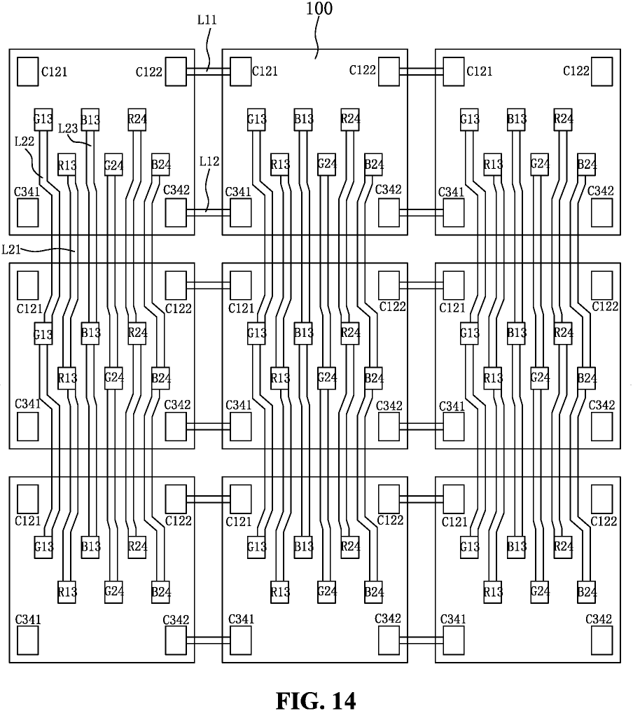

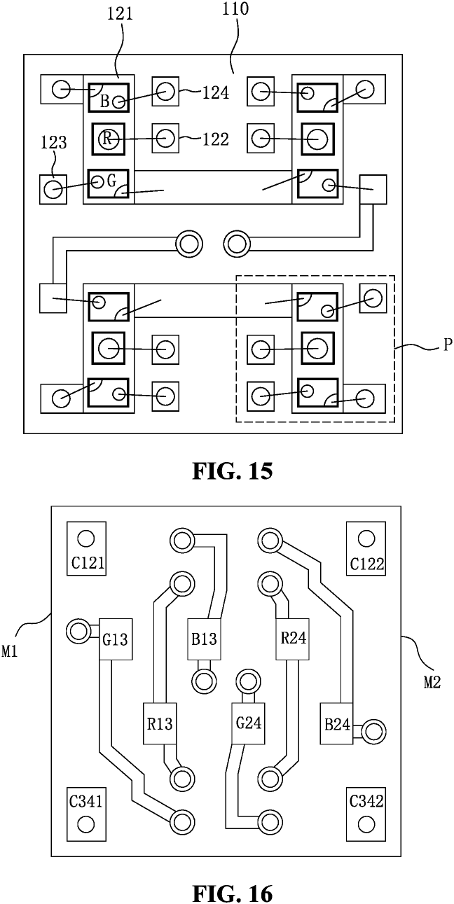

FIG. 14 is a partial structural diagram of an LED display module according to an embodiment of the present disclosure. FIG. 15 is a top view of an LED display unit according to an embodiment of the present disclosure. FIG. 16 is a bottom view of the LED display unit in FIG. 15. It is to be noted that, for simplicity of drawing, only wirings of the circuit board and pins of the LED display units are shown in FIG. 14. As shown in FIG. 14 to FIG. 16, the LED display module includes multiple LED display units 100 arranged in an array and a circuit board.

Illustratively, the LED display unit 100 is a “four-in-one” display unit, the display unit 100 includes two rows and two columns of total four pixel units P, and the pixel unit P includes LED light-emitting chips of three different light-emission colors: red (R), green (G), and blue (B), the LED light-emitting chip has an A-electrode and a B-electrode of opposite polarities. As an example, the A-electrode is a cathode and the B-electrode is an anode.

The LED display unit 100 includes a substrate 110, and the substrate 110 includes a pad layer and a pin layer which are arranged on two sides of the substrate 110, respectively. The pixel units P are arranged on a side of the pad layer away from the substrate 110, the pixel units P are electrically connected to the pad layer, and the pad layer is electrically connected to the pin layer.

The pin layer includes several A-electrode pins, each row of pixel units in the LED display unit is correspondingly provided with at least two A-electrode pins, the at least two A-electrode pins include a first A-electrode pin and a second A-electrode pin, the first A-electrode pin and the second A-electrode pin are arranged in the row direction, and the first A-electrode pin is electrically connected to the second A-electrode pin.

In the embodiment of the present disclosure, the LED display unit 100 is described by using an example in which two A-electrode pins are correspondingly provided in each row of pixel units of the LED display unit 100, and the two A-electrode pins are a first A-electrode pin and a second A-electrode pin, respectively. Illustratively, as shown in FIG. 15 and FIG. 16, in the LED display unit 100, three LED light-emitting chips of a pixel unit P are each fixed to a common pad 121, and cathodes of the three LED light-emitting chips are each electrically connected to the common pad 121. Illustratively, the red LED light-emitting chip R is a vertical-type chip, and a cathode of the red LED light-emitting chip R is fixed to the common pad 121 by a conductive material such as tin, so that electrical connection is achieved. The green LED light-emitting chip G and the blue LED light-emitting chip B are lateral chips, a cathode of the green LED light-emitting chip G and a cathode of the blue LED light-emitting chip B are electrically connected to the common pad 121 through metal lines, respectively, and two common pads 121 in each row of pixel units are electrically connected to each other through a connection line in the pad layer.

The first row of pixel units are correspondingly provided with a first A-electrode pin C121 and a second A-electrode pin C122, and a second row of pixel units are correspondingly provided with a first A-electrode pin C341 and a second A-electrode pin C342. The first A-electrode pin C121 and the second A-electrode pin C122 are electrically connected to the corresponding common pad 121 through a metal via, and the first A-electrode pin C341 and the second A-electrode pin C342 are electrically connected to the corresponding common pad 121 through a metal via, respectively, so that in the first row of pixel units of the LED display unit, the first A-electrode pin C121 and the second A-electrode pin C122 are electrically connected, the cathodes of the LED light-emitting chips are electrically connected to the first A-electrode pin C121 and the second A-electrode pin C122, and in the second row of pixel units, the first A-electrode pin C341 and the second A-electrode pin C342 are electrically connected, and cathodes of the LED light-emitting chips are electrically connected to the first A-electrode pin C341 and the second A-electrode pin C342. It is to be noted that in other embodiments of the present disclosure, two common pads in each row of pixel units may not be connected, but the first A-electrode pin and the second A-electrode pin may be electrically connected by a connection line in the pin layer, which is not limited in the embodiments of the present disclosure herein.

In the LED display module, in each row of LED display units, a second A-electrode pin of an i-th row of pixel units in a current LED display unit and a first A-electrode pin corresponding to an i-th row of pixel units in a subsequent LED display unit are electrically connected by the first wiring. Illustratively, as shown in FIG. 14, in each row of the LED display units, a second A-electrode pin C122 corresponding to a first row of pixel units in a current LED display unit is electrically connected to a first A-electrode pin C121 corresponding to a first row of pixel units in a subsequent LED display unit by a first wiring L11, and a second A-electrode pin C342 corresponding to a second row of pixel units in a current LED display unit and a first A-electrode pin C341 corresponding to a second row of pixel units in a subsequent LED display unit are electrically connected by a first wiring L12. In this way, the electrical connection of cathodes of all the LED light-emitting chips in the same row of pixel units in each row of LED display units in the LED display module is achieved.

In some embodiments of the present disclosure, the pin layer further includes several B-electrode pins, and the B-electrode pins include a first B-electrode pin. Each column of pixel units of the LED display unit 100 are correspondingly provided with first B-electrode pins, and the number of the first B-electrode pins is the same as the number of LED light-emitting chips in the pixel unit. Illustratively, as shown in FIG. 15 and FIG. 16, each column of pixel units of the LED display unit 100 are correspondingly provided with three first B-electrode pins, the number of which is the same as the number of the three LED light-emitting chips in the pixel unit P.

In each column of pixel units of the LED display unit 100, anodes of the LED light-emitting chips of the same light-emission color are electrically connected to the corresponding one first B-electrode pin in the column of pixel units. Illustratively, in the LED display unit 100, the anode of the red LED light-emitting chip R, the anode of the green LED light-emitting chip G, and the anode of the blue LED light-emitting chip B are electrically connected to corresponding anodes pads 122, 123, and 124 through metal lines, respectively. The two anode pads 122 corresponding to the red LED light-emitting chips R in a first column of pixel units are respectively connected to connection lines in the pin layer through metal vias and are electrically connected to a first B-electrode pin R13 corresponding to the red LED light-emitting chips R; the two anode pads 123 corresponding to the green LED light-emitting chips G in the first column of pixel units are respectively connected to connection lines in the pin layer through metal vias and are electrically connected to a first B-electrode pin G13 corresponding to the green LED light-emitting chips G; and the two anode pads 124 corresponding to the blue LED light-emitting chips B in the first column of pixel units are respectively connected to connection lines in the pin layer through metal vias and are electrically connected to a first B-electrode pin B13 corresponding to the blue LED light-emitting chips B. The two anode pads 122 corresponding to the red LED light-emitting chips R in a second column of pixel units are respectively connected to connection lines in the pin layer through metal vias and are electrically connected to a first B-electrode pin R24 corresponding to the red LED light-emitting chips R; the two anode pads 123 corresponding to the green LED light-emitting chips G in the second column of pixel units are respectively connected to connection lines in the pin layer through metal vias and are electrically connected to a first B-electrode pin G24 corresponding to the green LED light-emitting chips G; and the two anode pads 124 corresponding to the blue LED light-emitting chips B in the second column of pixel units are respectively connected to connection lines in the pin layer through metal vias and are electrically connected to a first B-electrode pin B24 corresponding to the blue LED light-emitting chips B.

In the LED display module, in each column of LED display units, the first B-electrode pins corresponding to the LED light-emitting chips of the same light-emission color in a j-th column of pixel units in a current LED display unit and in a j-th column of pixel units in a subsequent LED display unit are electrically connected by the second wiring. As shown in FIG. 14, in each column of the LED display units, in a first column of pixel units in a current LED display unit and in a first column of pixel units in a subsequent LED display unit, the first B-electrode pins R13 corresponding to the red LED light-emitting chips R are electrically connected by a second wiring L21, the first B-electrode pins G13 corresponding to the green LED light-emitting chips G are electrically connected by a second wiring L22, and the first B-electrode pins B13 corresponding to the blue LED light-emitting chips B are electrically connected by a second wiring L23; and in a second column of pixel units in a current LED display unit and in a second column of pixel units in a subsequent LED display unit, the first B-electrode pins R24 corresponding to the red LED light-emitting chips R are electrically connected by a second wiring L21, the first B-electrode pins G24 corresponding to the green LED light-emitting chips G are electrically connected by a second wiring L22, and the first B-electrode pins B24 corresponding to the blue LED light-emitting chips B are electrically connected by a second wiring L23. In this way, the electrical connection of the anodes of LED light-emitting chips of the same color in the same column of pixel units in each column of LED display units in the LED display module is achieved.

In the LED display module according to the embodiment of the present disclosure, the LED display units are arranged on the circuit board, the cathodes of the LED light-emitting chips in the same row of pixels in each row of the LED display units are connected by the first wirings on the circuit layer of the circuit board, and the anodes of the LED light-emitting chips of a same color in the same column of pixel units in each column of the LED display units are connected by the second wirings on the circuit layer of the circuit board, the first wiring and the second wiring extend in the row direction and the column direction respectively, and the first wirings and the second wirings do not cross each other. In this way, it can be achieved that the first wirings extending in the row direction and the second wirings extending in the column direction are arranged on the same circuit layer, thereby reducing the difficulty and cost of manufacturing the circuit board.

In some embodiments of the present disclosure, as shown in FIG. 14, the first wirings L11 and L12 are each arranged between two adjacent LED display units 100, and the second wirings L21, L22, and L23 pass through the vertical projections of the LED display units 100 on the circuit board. The first wirings L11 and L12 for connecting the cathodes of two adjacent LED display units in the row direction are not required to cross the entire LED display units, but are each simply arranged between the two adjacent LED display units, and the second wirings L21, L22, and L23 for connecting the anodes of two adj acent LED display units in the column direction can pass through the vertical projections of the LED display units on the circuit board. In this way, the space occupied by the first wirings extending in the row direction and the second wirings extending in the column direction can be saved, so that the first wirings extending in the row direction and the second wirings extending in the column direction are prevented from being short-circuited with each other due to too short distances therebetween.

In some embodiments of the present disclosure, a first A-electrode pin and a second A-electrode pin corresponding to each row of pixel units are respectively arranged at a first edge and a second edge on the substrate that are opposite to each other. Illustratively, as shown in FIG. 16, a first A-electrode pin C121 and a second A-electrode pin C122 corresponding to a first row of pixel units are arranged at the opposite first edge M1 and second edge M2 on the substrate 110 in the row direction, respectively, and a first A-electrode pin C341 and a second A-electrode pin C342 corresponding to a second row of pixel units are arranged at the opposite first edge M1 and second edge M2 on the substrate 110 in the row direction, respectively. In this way, the spacing between the first A-electrode pin C121 and the second A-electrode pin C122 corresponding to the first row of pixel units and the spacing between the first A-electrode pin C341 and the second A-electrode pin C342 corresponding to the second row of pixel units can be maximized, to provide a sufficient wiring arrangement space for the second wirings. Illustratively, in this embodiment, the first A-electrode pin C121, the second A-electrode pin C122, the first A-electrode pin C341, and the second A-electrode pin C342 are arranged at four corners of the substrate, respectively, and the first A-electrode pin C121 and the second A-electrode pin C122 are arranged on the same horizontal line, and the first A-electrode pin C341 and the second A-electrode pin C342 are arranged on another horizontal line, thereby facilitating wiring connection of the first wiring L11 and L12.

In some embodiments of the present disclosure, the first B-electrode pins are arranged on the substrate in a staggered manner, and the first B-electrode pins are arranged in a region surrounded by the first A-electrode pins and the second A-electrode pins. As shown in FIG. 14 and FIG. 16, six first B-electrode pins are arranged in a central region of the substrate 110 in a staggered manner and surrounded by the first A-electrode pins and the second A-electrode pins. In an embodiment, the first B-electrode pins G13, B13, and R24 are arranged in one row in the row direction, the first B-electrode pins R13, G24, and B24 are arranged in another row in the row direction, and the two rows of the first B-electrode pins are arranged in a staggered arrangement. As such, in the LED display module, the second wiring connecting the first B-electrode pins in two adjacent LED display units can pass through the space between two adjacent first B-electrode pins in another row, to avoid crossing of the second wirings on the circuit board. For example, as shown in FIG. 14, the second wiring L21 connecting the first B-electrode pins R13 may pass through the spacing between the first B-electrode pin G13 and the first B-electrode pin B13.

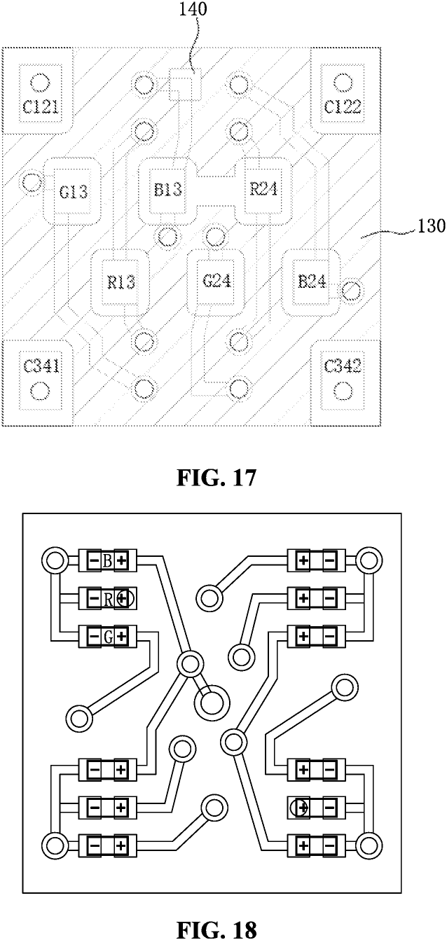

In some embodiments of the present disclosure, FIG. 17 is a bottom view of another LED display unit according to an embodiment of the present disclosure. As shown in FIG. 17, on the basis of the foregoing embodiments, the LED display unit 100 further includes an insulating layer 130, and the insulating layer 130 covers the connection lines connecting the A-electrode pins and connecting the B-electrode pins on the pin layer, and exposes the A-electrode pins and the B-electrode pins, thereby preventing the connection lines on the pin layer and the wirings on the circuit board from being short-circuited. In an embodiment, the material of the insulating layer 130 includes white ink, resin, green ink, and the like, having effects of insulation and protection.

In some embodiments of the present disclosure, as shown in FIG. 17, the insulating layer 130 is provided with a window 140 passing through the insulating layer 130, and the window 140 exposes part of a connection line in the pin layer. In this way, the metal connection line which differs significantly from the insulating layer 130 in color is formed at the window 140, which can have the function of distinguishing the orientation of the LED display unit and the polarity of the pin of the LED display unit, and thus, when an LED display unit is soldered to the circuit board, the error of connection of the LED display unit to the wirings on the circuit board caused by the error of identification of the LED display unit can be avoided.

It is to be noted that the arrangements of connection lines and pads in the pad layer are not limited in the embodiment of the present disclosure.

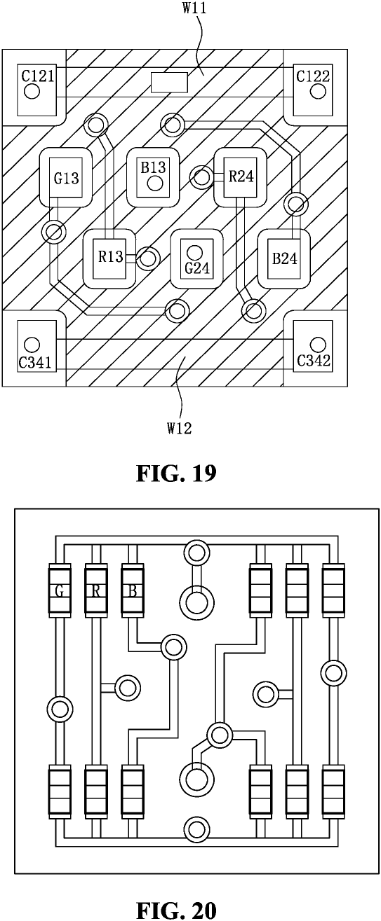

Illustratively, FIG. 18 is a top view of another LED display unit according to an embodiment of the present disclosure, and FIG. 19 is a bottom view of the LED display unit in FIG. 18. The embodiment differs from the foregoing embodiments in that the LED light-emitting chips in the pixel unit are flip chips, anodes and the cathodes of the flip chips are fixed to the corresponding anode pads and cathode pads by a conductive material (e.g., tin), respectively, three cathode pads of one pixel unit are connected by connection lines in the pad layer and are electrically connected to corresponding first A-electrode pin and second A-electrode pin by metal vias, and the first A-electrode pin and the second A-electrode pin corresponding to the same row of pixel units are electrically connected by a connection line in the pin layer. Illustratively, in a first row of pixel units, a first A-electrode pin C121 and a second A-electrode pin C122 are electrically connected by a connection line W11 in the pin layer. In a second row of pixel units, a first A-electrode pin C341 and a second A-electrode pin C342 are electrically connected by a connection line W12 in the pin layer. In the same column of pixel units, the anode pads of the LED light-emitting chips of the same light-emission color are electrically connected to the corresponding first B-electrode pins through connection lines in the pad layer and pin layer and metal vias. The same parts of this embodiment as those of the foregoing embodiments are not described here. For the LED module formed by the LED display units of this embodiment, reference may be made to FIG. 14, and details of which are not described here in the embodiment of the present disclosure.

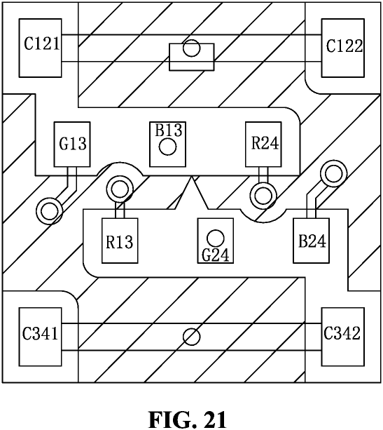

FIG. 20 is a top view of another LED display unit according to an embodiment of the present disclosure. FIG. 21 is a bottom view of the LED display unit in FIG. 20. The embodiment differs from the embodiments shown in FIG. 18 and FIG. 19 in that the LED light-emitting chips are arranged differently. In the embodiment shown in FIG. 18 and FIG. 19, three LED light-emitting chips in the pixel unit are arranged in the column direction. In this embodiment, three LED light-emitting chips in the pixel unit are arranged in the row direction. The same parts of this embodiment as those of the foregoing embodiments are not described here. For the LED module formed by the LED display units of this embodiment, reference may be made to FIG. 14, and details of which are not described here in the embodiment of the present disclosure.

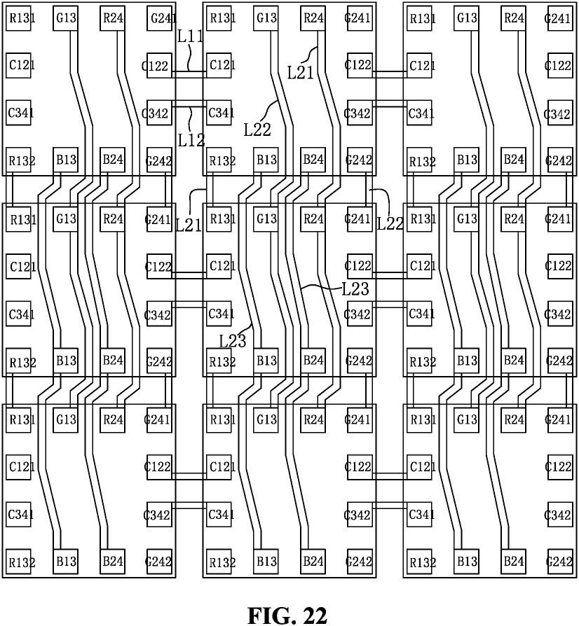

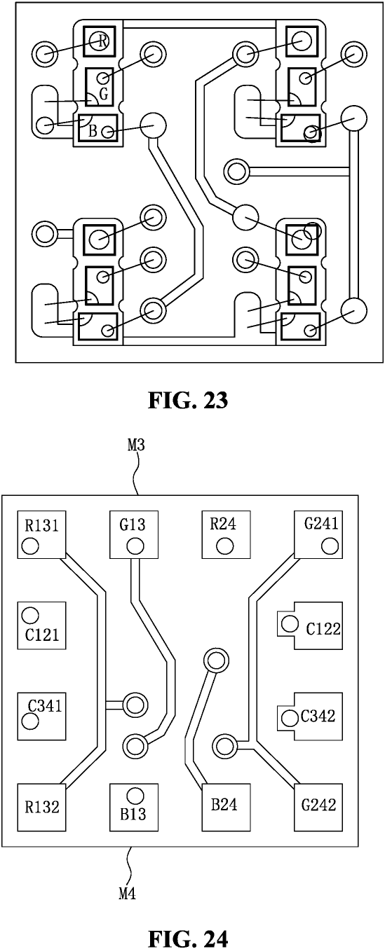

In order to facilitate the arrangement of the second wirings, FIG. 22 is a partial structural diagram of another LED display module according to an embodiment of the present disclosure, FIG. 23 is a top view of another LED display unit according to an embodiment of the present disclosure, and FIG. 24 is a bottom view of the LED display unit in FIG. 23.

This embodiment differs from the LED display module shown in FIG. 14 in that the B-electrode pins in the embodiment of the present disclosure further includes a second B-electrode pin, at least one of the first B-electrode pins is correspondingly provided with one second B-electrode pin, and the first B-electrode pin is electrically connected to the second B-electrode pin.

In at least one column of pixel units of the LED display unit, the B-electrode of at least one LED light-emitting chip of a same light-emission color are electrically connected to a first B-electrode pin and a second B-electrode pin corresponding to the column of pixel units.

In each column of LED display units, a second B-electrode pin corresponding to a j-th column of pixel units in a current LED display unit is electrically connected to a first B-electrode pin corresponding to a j-th column of pixel units in a subsequent LED display unit by a second wiring.

Illustratively, as shown in FIG. 23 and FIG. 24, in a first column of pixel units of the LED display unit 100, red LED light-emitting chips R are correspondingly provided with a first B-electrode pin R131 and a second B-electrode pin R132, and the first B-electrode pin R131 and the second B-electrode pin R132 are electrically connected through a connection line in the pin layer. In the first column of pixel units, anodes of the red LED light-emitting chips R are electrically connected to the first B-electrode pin R131 and the second B-electrode pin R132.

In a second column of pixel units, green LED light-emitting chips G are correspondingly provided with a first B-electrode pin G241 and a second B-electrode pin G242. The first B-electrode pin G241 and the second B-electrode pin G242 are electrically connected by a connection line in the pin layer. In the second column of pixel units, anodes of the green LED light-emitting chips G are electrically connected to the first B-electrode pin G241 and the second B-electrode pin G242.

In this embodiment, as shown in FIG. 22, in each row of LED display units, a second A-electrode pin C122 corresponding to a first row of pixel units in a current LED display unit is electrically connected to a first A-electrode pin C121 corresponding to the first row of pixel units in a subsequent LED display unit by a first wiring L11, and a second A-electrode pin C342 corresponding to a second row of pixel units in a current LED display unit is electrically connected to a first A-electrode pin C341 corresponding to the second row of pixel units in a subsequent LED display unit by a first wiring L12. In this way, the electrical connection of cathodes of all the LED light-emitting chips in the same row of pixel units in each row of the LED display units in the LED display module is achieved.

In each column of LED display units, a second B-electrode pin R132 corresponding to the red LED light-emitting chips R in a first column of pixel units in a current LED display unit and a first B-electrode pin R131 corresponding to the red LED light-emitting chips R in the first column of pixel units in a subsequent LED display unit are electrically connected by a second wiring L21, first B-electrode pins G13 corresponding to the green LED light-emitting chips G are electrically connected by a second wiring L22, and first B-electrode pins B13 corresponding to the blue LED light-emitting chips B are electrically connected by a second wiring L23. A second B-electrode pin G242 corresponding to the green LED light-emitting chips G in a second column of pixel units in a current LED display unit and a first B-electrode pin G241 corresponding to the green LED light-emitting chips G in the second column of pixel units in a subsequent LED display unit are electrically connected by a second wiring L22, first B-electrode pins R24 corresponding to the red LED light-emitting chips R are electrically connected by a second wiring L21, and first B-electrode pins B24 corresponding to the blue LED light-emitting chips B are electrically connected by a second wiring L23. In this way, the electrical connection of anodes of LED light-emitting chips of the same color in the same column of pixel units in each column of LED display units in the LED display module is achieved.

In some embodiments of the present disclosure, the first B-electrode pin and the corresponding second B-electrode pin are arranged at a third edge and a fourth edge on the substrate that are opposite to each other in the column direction, respectively. Illustratively, as shown in FIG. 24, in the LED display unit, the first B-electrode pin R131 and the second B-electrode pin R132 are arranged at the third edge M3 and the fourth edge M4 on the substrate 110 that are opposite to each other in the column direction, respectively, and the first B-electrode pin G241 and the second B-electrode pin G242 are arranged at the third edge M3 and the fourth edge M4 on the substrate 110 that are opposite to each other in the column direction, respectively. Illustratively, the first B-electrode pin R131 and the second B-electrode pin R132 are located on the same horizontal line extending in the column direction, and the first B-electrode pin G241 and the second B-electrode pin G242 are located on another horizontal line extending in the column direction, thereby facilitating connection of the second wirings L21 and L22.

The first B-electrode pin and the second B-electrode pin are electrically connected, and thus, the anodes of the LED light-emitting chips of the same light-emission color are electrically connected to the corresponding first B-electrode pins and corresponding second B-electrode pins, and the second B-electrode pin corresponding to the second column of pixel units in a current LED display unit and the first B-electrode pin corresponding to the second column of pixel units in the subsequent LED display unit are electrically connected by the second wiring, and the second wiring can be arranged between two adjacent LED display units, so that more space can be reserved for other second wirings.

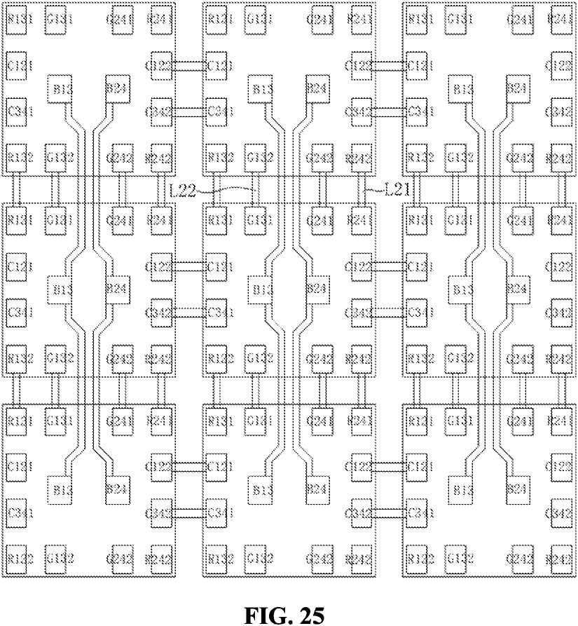

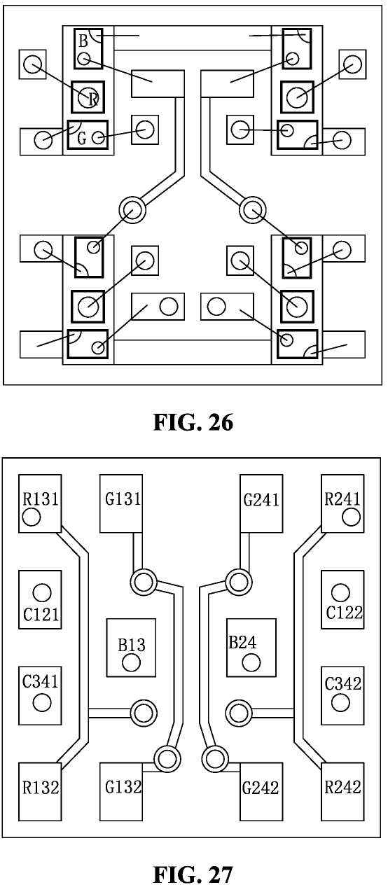

FIG. 25 is a partial structural diagram of another LED display module according to an embodiment of the present disclosure. FIG. 26 is a top view of another LED display unit according to an embodiment of the present disclosure. FIG. 27 is a bottom view of the LED display unit in FIG. 26. This embodiment differs from the LED display unit shown in FIG. 23 and FIG. 24 in that in the LED display unit, green LED light-emitting chips G of the first column of pixel units are correspondingly provided with a first B-electrode pin G131 and a second B-electrode pin G132, and the first B-electrode pin G131 and the second B-electrode pin G132 are electrically connected by a connection line in the pin layer; and red LED light-emitting chips R of the second column of pixel units are correspondingly provided with a first B-electrode pin R241 and a second B-electrode pin R242, and the first B-electrode pin R241 and the second B-electrode pin R242 are electrically connected by a connection line in the pin layer. The first B-electrode pin G131 and the second B-electrode pin G132 are arranged at the third edge M3 and the fourth edge M4 on the substrate 110 that are opposite to each other in the column direction, respectively; and the first B-electrode pin R241 and the second B-electrode pin R242 are arranged at the third edge M3 and the fourth edge M4 on the substrate 110 that are opposite to each other in the column direction, respectively.

This embodiment differs from the embodiment in FIG. 22 in that in the LED display module, a second B-electrode pin G132 corresponding to green LED light-emitting chips G of a first column of pixel units in a current LED display unit is electrically connected to a first B-electrode pin G131 corresponding to green LED light-emitting chips G of a first column of pixel units in a subsequent LED display unit by a second wiring L22, and a second B-electrode pin R242 corresponding to red LED light-emitting chips R of a second column of pixel units in a current LED display unit is electrically connected to a first B-electrode pin R241 corresponding to red LED light-emitting chips R of a second column of pixel units in a subsequent LED display unit through a second wiring L21.

It is to be noted that in the above embodiment, the LED display unit is described by an example in which the LED display unit is a “four-in-one” display unit composed of two rows and two columns of pixel units. In other embodiments of the present disclosure, the LED display unit may include only one pixel unit, or include multiple pixel units (for example, two rows and three columns, etc.), which is not limited here in the embodiments of the present disclosure.

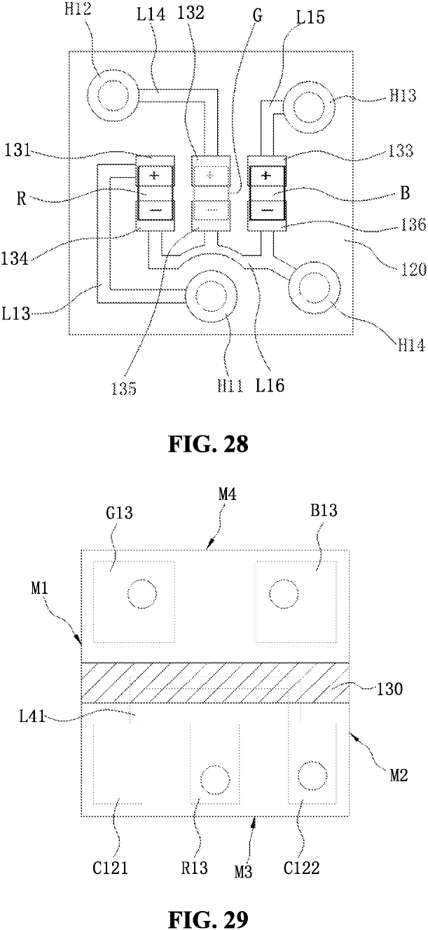

FIG. 28 is a top view of another LED display unit according to an embodiment of the present disclosure, and FIG. 29 is a bottom view of the LED display unit in FIG. 28. As shown in FIG. 28 and FIG. 29, the LED display unit includes a substrate 120 and three LED light-emitting chips of different light-emission colors (a red LED light-emitting chip R, a green LED light-emitting chip G, and a blue LED light-emitting chip B, respectively).

The substrate 120 includes a pad layer and a pin layer arranged on opposite surfaces of the substrate 120, respectively. Illustratively, as shown in FIG. 28 and FIG. 29, the pad layer and the pin layer are arranged on a top surface (as shown in the top view) and a bottom surface (as shown in the bottom view) of the substrate 120, respectively. The pin layer includes three first B-electrode pins (denoted by reference numerals R13, G13, B13, respectively) and a first A-electrode pin C121 and a second A-electrode pin C122. The first A-electrode pin C121 and the second A-electrode pin C122 are located at the first edge M1 and the second edge M2 on the substrate that are opposite to each other, respectively.

The pad layer is electrically connected to the pin layer, and the LED light-emitting chips are fixed onto the pad layer and electrically connected to the pad layer, so that the B-electrodes of the LED light-emitting chips are electrically connected to the corresponding first B-electrode pins, and the A-electrodes of the LED light-emitting chips are electrically connected to the first A-electrode pin C121 and the second A-electrode pin C122. Illustratively, a B-electrode of a red LED light-emitting chip R is electrically connected to a first B-electrode pin R13, a B-electrode of a green LED light-emitting chip G is electrically connected to a first B-electrode pin G13, and a B-electrode of a blue LED light-emitting chip B is electrically connected to a first B-electrode pin B13. A-electrodes of the three LED light-emitting chips are each electrically connected to the first A-electrode pin C121 and the second A-electrode pin C122.

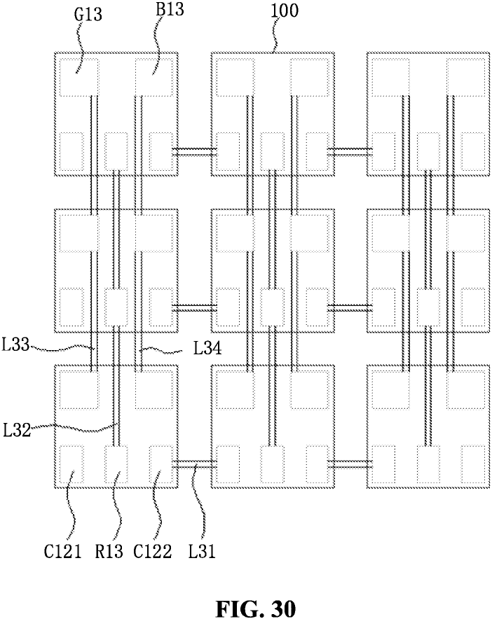

FIG. 30 is a partial structural diagram of an LED display module according to an embodiment of the present disclosure. As shown in FIG. 30, the display module includes a circuit board and multiple LED display units as shown in FIG. 28 and FIG. 29 (only wirings of the circuit board are shown for simplicity of drawing). As shown in FIG. 30, the multiple LED display units 100 are arranged in an array on a circuit board, and a surface of the circuit board close to the LED display units 100 is provided with a circuit layer.

In order to achieve that A-electrodes of all the light-emitting chips in the same row are electrically connected, and B-electrodes of the light-emitting chips of the same light-emission color in the same column are electrically connected, as shown in FIG. 30, in each row of LED display units, a second A-electrode pin C122 in a current LED display unit and close to the second edge M2 is electrically connected to a first A-electrode pin C121 in a subsequent LED display unit and close to the first edge M1 by a first wiring L31 in the circuit layer, and the first wiring L31 extends in the row direction. In each column of LED display units, first B-electrode pins of the LED light-emitting chips of the same light-emission color in a current LED display unit and in a subsequent LED display unit are electrically connected by second wirings in the circuit layer, and the second wirings extend in the column direction. Illustratively, in each column of LED display units, first B-electrode pins R13 in a current LED display unit and in a subsequent LED display unit are electrically connected by a second wiring L32. Similarly, first B-electrode pins G13 in a current LED display unit and in a subsequent LED display unit are electrically connected by a second wiring L33, and first B-electrode pins B13 in a current LED display unit and in a subsequent LED display unit are electrically connected by a second wiring L34.

In the LED display unit according to the embodiment of the present disclosure, the first A-electrode pin and the second A-electrode pin are electrically connected and are respectively located at the opposite first edge and second edge on the substrate; therefore, when the display module is formed, in each row of LED display units, the second A-electrode pin in a current LED display unit and close to the second edge and the first A-electrode pin in a subsequent LED display unit and close to the first edge are electrically connected by the wiring between the two adjacent LED display units, and thus, the electrical connection of the first A-electrode pins to the second A-electrode pins of all the LED display units in the same row respectively can be achieved, and the wiring for connecting the first A-electrode pin to the second A-electrode pin is not required to extend across the entire LED display unit and is simply arranged between two adjacent LED display units, and the wiring for connecting the first B-electrodes may extend across the projections of the LED display units on the circuit board. In this way, the wirings extending in the row direction and the wirings extending in the column direction on the circuit board are prevented from crossing, and the wirings extending in the row direction and the wirings extending in the column direction can thus be arranged in the same layer, thereby reducing the manufacturing cost of the circuit board.

The pad layer is electrically connected to the pin layer. Illustratively, in this embodiment, the pad layer and the pin layer may be electrically connected by metal vias passing through the substrate 120. In other embodiments of the present disclosure, the pad layer and the pin layer may also be connected by other electrical connecting parts, and the manner of connection between the pad layer and the pin layer is not limited in the present disclosure.

In the embodiment of the present disclosure, the pad layer includes first pads and second pads, the number of the first pads is the same as the number of the LED light-emitting chips, and the number of the second pads is the same as the number of the LED light-emitting chips, B-electrodes of the LED light-emitting chips are electrically connected to the corresponding first pads, and A-electrodes of the LED light-emitting chips are electrically connected to the corresponding second pads. The first B-electrode pins corresponding the first pads are electrically connected respectively. The second pads are electrically connected to each other and electrically connected to the first A-electrode pin and the second A-electrode pin. Illustratively, as shown in FIG. 28 and FIG. 29, in this embodiment, each of the three LED light-emitting chips is a flip chip, and the B-electrode and the A-electrode of the flip chip are both located on a backlight face of the flip chip. The pad layer includes three first pads (denoted by reference numerals 131, 132, and 133, respectively) and three second pads (denoted by reference numerals 134, 135, and 136, respectively).

The B-electrodes of the three LED light-emitting chips are fixed to the corresponding first pads by a conductive material (for example, tin) to achieve electrical connection to the first pads. For example, the B-electrode of the red LED light-emitting chip R is fixed to the first pad 131, the B-electrode of the green LED light-emitting chip G is fixed to the first pad 132, and the B-electrode of the blue LED light-emitting chip B is fixed to the first pad 133. The A-electrodes of the three LED light-emitting chips are fixed to the corresponding second pads by a conductive material (e.g., tin) to achieve electrical connection to the second pads. For example, the A-electrode of the red LED light-emitting chip R is fixed to the second pad 134, the A-electrode of the green LED light-emitting chip G is fixed to the second pad 135, and the A-electrode of the blue LED light-emitting chip B is fixed to the second pad 136.

The first pads are electrically connected to the corresponding first B-electrode pins. Illustratively, as shown in FIG. 28 and FIG. 29, a first pad 131 is electrically connected to a metal via H11 through a connection line L13, and the metal via H11 passes through the substrate 120 and is electrically connected to the first B-electrode pin R13. The first pad 132 is electrically connected to the metal via H12 through a connection line L14, and the metal via H12 passes through the substrate 120, and is electrically connected to the first B-electrode pin G13. The first pad 133 is electrically connected to the metal via H13 through the connection line L15, and the metal via H13 passes through the substrate 120 and is electrically connected to the first B-electrode pin B13.

The second pads are electrically connected together and are electrically connected to the first A-electrode pin and the second A-electrode pin. Illustratively, as shown in FIG. 28 and FIG. 29, the second pads are electrically connected to a metal via H14 through a connection line L16, the metal via H14 passes through the substrate 120 and is electrically connected to the second A-electrode pin, and the first A-electrode pin is electrically connected to the second A-electrode pins via a connection line L41 in the pin layer. In the embodiment of the present disclosure, the second pads are electrically connected to the first A-electrode pin and the second A-electrode pin through the metal via and the connection line, and the connection line is located in the pin layer and is electrically connected to the first A-electrode pin and the second A-electrode pin. In other embodiments of the present disclosure, the second pads may also be electrically connected to the first A-electrode pin and the second A-electrode pin through one or more metal vias, which is not described further in the embodiment of the present disclosure.

In some embodiments of the present disclosure, as shown in FIG. 29, in order to avoid that the connection line L41 in the pin layer is in contact with one or more wirings on the circuit board to cause short-circuit, the LED display unit is further provided with an insulating layer 130, and the insulating layer 130 covers the connection line L41 to protect the connection line L41 to allow the connection line L41 and the circuit board to be insulated from each other.

In other embodiments of the present disclosure, all the second pads may be formed into an integral structure to form a common pad, so as to achieve the electrical connection of the second pads. The rest connection relationships are the same as those in FIG. 28 and FIG. 29, which is not described further in the embodiment of the present disclosure.

In some embodiments of the present disclosure, first B-electrode pins are arranged on the substrate in a staggered manner, and further, the first B-electrode pins are located at the third edge and the fourth edge on the substrate that are opposite to each other. Illustratively, as shown in FIG. 29, the first B-electrode pins R13, G13, and B13 are arranged on the substrate 120 in a staggered manner, and the first B-electrode pin R13 is located at the third edge M3 on the substrate 120, and the first B-electrode pin G13 and the first B-electrode pin B13 are located at the fourth edge M4 on the substrate 120, so as to avoid the crossing of the wirings connecting the first B-electrode pins on the circuit board, to allow the wirings connecting the first B-electrode pins to pass through the projections of the LED display units on the circuit board as shown in FIG. 30, and further, the wirings extending in the row direction and the wirings extending in the column direction can be arranged in the same layer, and the three circuit layers required to be provided in the related art is simplified to that only one circuit layer is required, thereby reducing the manufacturing cost of the circuit board.

In some embodiments of the present disclosure, the first B-electrode pin is located between the first A-electrode pin and the second A-electrode pin. Illustratively, as shown in FIG. 29, the first B-electrode pin R13 is arranged between the first A-electrode pin C121 and the second A-electrode pin C122, the first B-electrode pins G13 and B13 are arranged along the fourth edge M4, and the first B-electrode pins G13 and B13, the first A-electrode pin C121 and the second A-electrode pin C122 are arranged at four corners of substrate 120, respectively, so that the first A-electrode pin C121 and the second A-electrode pin C122 are located at the first edge M1 and the second edge M2 on the substrate 120 that are opposite to each other, respectively, and the first B-electrode pins R13, G13, and B13 are located at the third edge M3 and the fourth edge M4 on the substrate 120 that are opposite to each other, respectively.

In some embodiments of the present disclosure, the area of the first B-electrode pin between the first A-electrode pin and the second A-electrode pin is different from the area of each of the other two first B-electrode pins. Illustratively, as shown in FIG. 30, the area of each of the first B-electrode pin R13, the first A-electrode pin C121, and the second A-electrode pin C122 is smaller than the area of each of the first B-electrode pins G13 and B13. The pins are difference in area; therefore, in the process of soldering an LED display unit to the circuit board, the position of the LED display unit can be determined according to the difference, so that misconnection of the positions of pins in soldering is avoided.

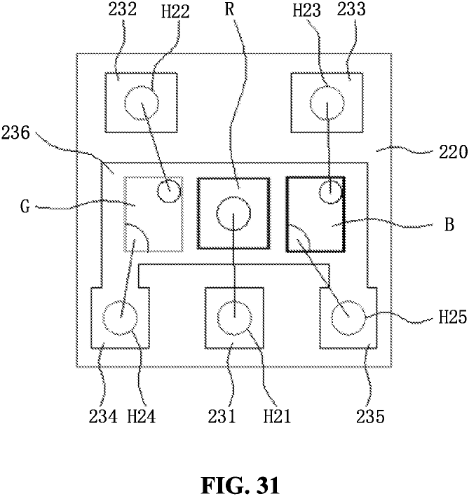

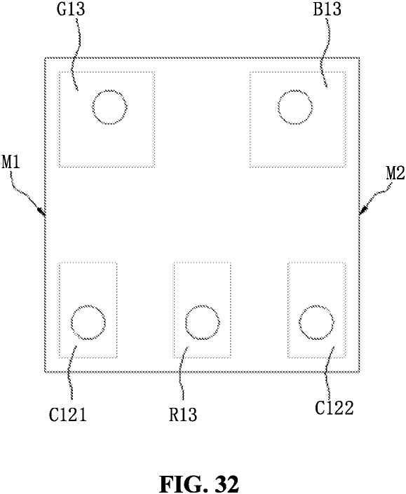

The above-described embodiments illustrate the present disclosure by taking LED light-emitting chips being flip chips as an example. In other embodiments of the present disclosure, the LED light-emitting chips may be lateral chips or vertical chips, which is not limited here in the embodiments of the present disclosure. The B-electrode and the A-electrode of a lateral chip are both located on the light-emitting surface of the lateral chip, and the B-electrode and the A-electrode of a vertical chip are respectively located on the light-emitting surface and the backlight surface of the vertical chip. Illustratively, FIG. 31 is a top view of another LED display unit according to an embodiment of the present disclosure, and FIG. 32 is a bottom view of the LED display unit in FIG. 31. As shown in FIG. 31 and FIG. 32, the LED display unit includes a substrate 220 and three LED light-emitting chips of different light-emission colors (a red LED light-emitting chip R, a green LED light-emitting chip G, and a blue LED light-emitting chip B, respectively).

The substrate 220 includes a pad layer and a pin layer, the pad layer and the pin layer are arranged on a top surface (as shown in the top view) and a bottom surface (as shown in the bottom view) of the substrate 220, respectively. The pin layer includes three first B-electrode pins (denoted by reference numerals R13, G13, B13, respectively), a first A-electrode pin C121 and a second A-electrode pin C122. The first A-electrode pin C121 and the second A-electrode pin C122 are located at a first edge M1 and a second edge M2 on the substrate that are opposite to each other, respectively.

In this embodiment, the red LED light-emitting chip R is a vertical chip, and the green LED light-emitting chip G and the blue LED light-emitting chip B are lateral chips. Apparently, in other embodiments of the present disclosure, the three LED light-emitting chips may all be lateral chips or vertical chips, which is not limited here in the embodiments of the present disclosure.

The pad layer includes three first pads (denoted by reference numerals 231, 232, and 233, respectively) and three second pads (denoted by reference numerals 234, 235, and 236, respectively).

Illustratively, a B-electrode of the red light-emitting chip R is electrically connected to the first pad 231 by a metal line, and the first pad 231 is electrically connected to the first B-electrode pin R13 through a metal via H21 passing through the substrate 220. A B-electrode of the green light-emitting chip G is electrically connected to the first pad 232 through a metal line, and the first pad 232 is electrically connected to the first B-electrode pin G13 through a metal via H22 passing through the substrate 220. A B-electrode of the blue light-emitting chip B is electrically connected to the first pad 233 through a metal line, and the first pad 233 is electrically connected to the first B-electrode pin B13 through a metal via H23 passing through the substrate 220.

The three LED light-emitting chips are fixed onto the second pad 236, and the three second pads 234, 235, and 236 are integrated to form a common pad. An A-electrode of the red LED light-emitting chip R is electrically connected to the second pad 236 through a conductive material such as tin, an A-electrode of the green LED light-emitting chip G is electrically connected to the second pad 234 through a metal line, and an A-electrode of the blue LED light-emitting chip B is electrically connected to the second pad 235 through a metal line. The second pad 234 is electrically connected to the first A-electrode pin C121 through a metal via H24 passing through the substrate 220, and the second pad 235 is electrically connected to the second A-electrode pin C122 through a metal via H25 passing through the substrate 220. In other embodiments of the present disclosure, the three second pads 234, 235 and 236 may also be electrically connected by a connection line located in the pad layer, which is not limited here in the embodiments of the present disclosure. The arrangement of the pins in the pin layer in this embodiment is the same as the arrangement of the pins in the pin layer in FIG. 29, which is not described again in this embodiment of the present disclosure herein. Accordingly, the circuit board provided for the LED display units in this embodiment is the same as that in FIG. 30, which is not described again here in this embodiment of the present disclosure.

The LED display unit according to this embodiment has the same functions and effects as those of the LED display units according to the foregoing embodiments, and the functions and effects are not described again here in this embodiment of the present disclosure.

A display device is further provided according to an embodiment of the present disclosure, and the display device includes an LED display module according to any of the foregoing embodiments. For example, the display device may be a display, a television, a smartphone, a tablet computer, or the like, which is not limited here in the embodiment of the present disclosure.

In the description of this embodiment, it is to be appreciated that the orientational or positional relationships indicated by terms “above”, “below”, “left”, “right” and the like are based on the orientational or positional relationships shown in the drawings, merely for ease of description and simplifying operation, rather than indicating or implying that the referred device or element must have a specific orientation and is constructed and operated in a specific orientation, and thus they are not to be construed as limiting the present disclosure.

In the description of the specification, the description of reference terms “an embodiment” or “example” means that specific characteristics, structures, materials or features described in connection with the embodiment or example are included in at least one embodiment or example of the present disclosure. In the specification, the illustrative description of the preceding terms does not necessarily refer to the same embodiment or example.

It is to be noted that the preceding are only preferred embodiments of the present disclosure and technical principles used therein. It is be appreciated by the person skilled in the art that the present disclosure is not limited to the embodiments described herein, and that various obvious changes, modifications, combinations and substitutions can be made by the person skilled in the art without departing from scope of the present disclosure. Therefore, while the present disclosure has been described in detail through the above-mentioned embodiments, the present disclosure is not limited to the above-mentioned embodiments and may include more other equivalent embodiments without departing from the concept of the present disclosure. The scope of the present disclosure is determined by the scope of the appended claims.

What is claimed is:

1. A light-emitting diode (LED) display module, comprising:
a plurality of LED display units arranged in an array, wherein each of the plurality of LED display units comprises m rows and n columns of pixel units, each of the pixel units comprises a plurality of LED light-emitting chips of different light-emission colors, each of the plurality of LED light-emitting chips has an A-electrode and a B-electrode, wherein a polarity of the A-electrode is opposite to a polarity of the B-electrode, and m and n are positive integers greater than or equal to 1; and
a circuit board, wherein the plurality of LED display units are arranged on the circuit board, a surface of the circuit board close to the plurality of LED display units is provided with a circuit layer, the circuit layer comprises a plurality of first wirings and a plurality of second wirings, the plurality of first wirings extend in a row direction, the plurality of second wirings extend in a column direction, and the plurality of first wirings and the plurality of second wirings do not cross each other;
wherein in each row of LED display units among the plurality of LED display units, A-electrodes of LED light-emitting chips in an i-th row of pixel units in a current LED display unit and A-electrodes of LED light-emitting chips in an i-th row of pixel units in a subsequent LED display unit are electrically connected by one first wiring;
wherein in each column of LED display units among the plurality of LED display units, B-electrodes of LED light-emitting chips of a same color in a j-th column of pixel units in a current LED display unit and in a j-th column of pixel units in a subsequent LED display unit are electrically connected by one second wiring; and
wherein 1 ≤ i ≤ m, 1 ≤ j ≤ n, and i and j are positive integers.

2. The LED display module according to claim 1, wherein
one LED display unit further comprises a substrate, the substrate is provided with a pin layer electrically connected to the pixel units, the pixel units and the pin layer are respectively provided on two sides of the substrate, and the pin layer comprises a plurality of A-electrode pins;
each row of pixel units in the one LED display unit is provided with at least two A-electrode pins, the at least two A-electrode pins comprise a first A-electrode pin and a second A-electrode pin, the first A-electrode pin and the second A-electrode pin are arranged in the row direction, and the first A-electrode pin is electrically connected to the second A-electrode pin;
A-electrodes of LED light-emitting chips in each row of pixel units in the one LED display are electrically connected to a respective one first A-electrode pin and a respective one second A-electrode pin corresponding to the each row of pixel units; and
in each row of LED display units, a second A-electrode pin corresponding to an i-th row of pixel units in a current LED display unit and a first A-electrode pin corresponding to an i-th row of pixel units in a subsequent LED display unit are electrically connected by one first wiring.

3. The LED display module according to claim 2, wherein
the pin layer further comprises a plurality of B-electrode pins, and the plurality of B-electrode pins comprise first B-electrode pins;
each column of pixel units in the one LED display unit is provided with the first B-electrode pins, and a number of the first B-electrode pins is the same as a number of LED light-emitting chips in the each column of pixel units;
B-electrodes of LED light-emitting chips of a same light-emission color in each column of pixel units in the one LED display unit are electrically connected to a respective one of the first B-electrode pins in the each column of pixel units; and
in each column of LED display units, first B-electrode pins corresponding to LED light-emitting chips of a same light-emission color in a j-th column of pixel units in a current LED display unit and in a j-th column of pixel units in a subsequent LED display unit are electrically connected by one second wiring.

4. The LED display module according to claim 3, wherein
each row of pixel units in the one LED display unit is provided with two A-electrode pins, and the two A-electrode pins are the first A-electrode pin and the second A-electrode pin, respectively;
A-electrodes of LED light-emitting chips in each row of pixel units in the one LED display unit are electrically connected to the first A-electrode pin and the second A-electrode pin corresponding to the each row of pixel units; and
in each row of LED display units, a second A-electrode pin corresponding to an i-th row of pixel units in a current LED display unit and a first A-electrode pin corresponding to an i-th row of pixel units in a subsequent LED display unit are electrically connected by one first wiring.

5. The LED display module according to claim 4, wherein the first A-electrode pin and the second A-electrode pin corresponding to each row of pixel units are arranged at a first edge on the substrate and a second edge on the substrate in the row direction, respectively, wherein the first edge is opposite to the second edge.

6. The LED display module according to claim 5, wherein the first B-electrode pins are arranged on the substrate in a staggered manner, and the first B-electrode pins are arranged in a region surrounded by first A-electrode pins and second A-electrode pins.

7. The LED display module according to claim 4, wherein the B-electrode pins further comprise a second B-electrode pin, at least one of the first B-electrode pins is provided with one second B-electrode pin, and the at least one of the first B-electrode pins is electrically connected to the second B-electrode pin;
in at least one column of pixel units in the one LED display unit, a B-electrode of at least one LED light-emitting chip of LED light-emitting chips of a same light-emission color is electrically connected to one first B-electrode pin and one second B-electrode pin corresponding to the at least one column of pixel units; and
in each column of LED display units, a second B-electrode pin corresponding to a j-th column of pixel units in a current LED display unit is electrically connected to a first B-electrode pin corresponding to a j-th column of pixel units in a subsequent LED display unit by one second wiring.

8. The LED display module according to claim 7, wherein one first B-electrode pin and one second B-electrode pin corresponding to the one first B-electrode pin are arranged at a third edge on the substrate and a fourth edge on the substrate in the column direction, respectively, wherein the third edge is opposite to the fourth edge.

9. The LED display module according to claim 3, wherein the one LED display unit further comprises an insulating layer, and the insulating layer covers connection lines connecting the plurality of A-electrode pins and connecting the plurality of B-electrode pins in the pin layer and exposes the plurality of A-electrode pins and the plurality of B-electrode pins.

10. The LED display module according to claim 9, wherein the insulating layer is provided with a window passing through the insulating layer, and the window exposes a part of the connection lines in the pin layer.

11. The LED display module according to claim 1, wherein the plurality of first wirings are arranged between two adjacent LED display units, and the plurality of second wirings pass through vertical projections of the plurality of LED display units on the circuit board.

12. The LED display module according to claim 5, wherein the first B-electrode pins are arranged on the substrate in a staggered manner.

13. The LED display module according to claim 12, wherein the first B-electrode pins are located at a third edge on the substrate and a fourth edge on the substrate, respectively, wherein the third edge is opposite to the fourth edge.

14. The LED display module according to claim 13, wherein the one LED display unit comprises three LED light-emitting chips of different light-emission colors, and the pin layer comprises three first B-electrode pins, wherein one first B-electrode pin of the three first B-electrode pins is located between the first A-electrode pin and the second A-electrode pin.

15. The LED display module according to claim 14, wherein an area of the one first B-electrode pins between the first A-electrode pin and the second A-electrode pin is different from an area of each of the other two first B-electrode pins of the three first B-electrode pins.

16. The LED display module according to claim 5, wherein the one LED display unit further
comprises a pad layer, the pad layer is electrically connected to the pin layer, and LED light-emitting chips of the one LED display unit are fixed onto the pad layer and electrically connected to the pad layer;
the pad layer comprises first pads and second pads, a number of the first pads is the same as a number of the LED light-emitting chips, and a number of the second pads is the same as the number of the LED light-emitting chips, each of B-electrodes of the LED light-emitting chips is electrically connected to a respective one of the first pads, and each of A-electrodes of the LED light-emitting chips is electrically connected to a respective one of the second pads;
each of the first pads is electrically connected to a respective one of the first B-electrode pins; and
the second pads are electrically connected together and are electrically connected to the first A-electrode pin and the second A-electrode pin.

17. The LED display module according to claim 16, wherein
the second pads are electrically connected to the first A-electrode pin and the second A-electrode pin through a metal via; or
the second pads are electrically connected to the first A-electrode pin and the second A-electrode pin through a metal via and a connection line, and the connection line is located on the pin layer and is electrically connected to the first A-electrode pin and the second A-electrode pin.

18. The LED display module according to claim 16, wherein the second pads are electrically connected by a connection line in the pad layer, or the second pads are an integrated structure, to form a common pad.

19. A display device, comprising:
an LED display module comprising:
a plurality of LED display units arranged in an array, wherein each of the plurality of LED display units comprises m rows and n columns of pixel units, each of the pixel units comprises a plurality of LED light-emitting chips of different light-emission colors, each of the plurality of LED light-emitting chips has an A-electrode and a B-electrode, wherein a polarity of the A-electrode is opposite to a polarity of the B-electrode, and m and n are positive integers greater than or equal to 1; and
a circuit board, wherein the plurality of LED display units are arranged on the circuit board, a surface of the circuit board close to the plurality of LED display units is provided with a circuit layer, the circuit layer comprises a plurality of first wirings and a plurality of second wirings, the plurality of first wirings extend in a row direction, the plurality of second wirings extend in a column direction, and the plurality of first wirings and the plurality of second wirings do not cross each other;
wherein in each row of LED display units among the plurality of LED display units, A-electrodes of LED light-emitting chips in an i-th row of pixel units in a current LED display unit and A-electrodes of LED light-emitting chips in an i-th row of pixel units in a subsequent LED display unit are electrically connected by one first wiring;
wherein in each column of LED display units among the plurality of LED display units, B-electrodes of LED light-emitting chips of a same color in a j-th column of pixel units in a current LED display unit and in a j-th column of pixel units in a subsequent LED display unit are electrically connected by one second wiring; and
wherein 1 ≤ i ≤ m, 1 ≤ j ≤ n, and i and j are positive integers.
